(19) United States
(12) Patent Application Publication
(10) Pub. No.: US 2024/0021503 A1
(43) Pub. Date: Jan. 18, 2024

(54) ELECTRONIC COMPONENT PACKAGE, ELECTRONIC COMPONENT UNIT, AND METHOD OF MANUFACTURING ELECTRONIC COMPONENT PACKAGE

(71) Applicant: Murata Manufacturing Co., Ltd., Kyoto (JP)

(72) Inventors: Yoshihito OTSUBO, Nagaokakyo-shi (JP); Takamitsu NAKAMURA, Nagaokakyo-shi (JP)

(21) Appl. No.: 18/474,751

(22) Filed: Sep. 26, 2023

Related U.S. Application Data
(63) Continuation of application No. PCT/JP2022/007319, filed on Feb. 22, 2022.

(30) Foreign Application Priority Data
Mar. 29, 2021 (JP) 2021-055802

(51) Int. Cl. H01L 23/495; H01L 23/367; H01L 23/00; H01L 25/065; H01L 23/552

(52) U.S. Cl. CPC H01L 23/49531; H01L 23/4951; H01L 23/3675; H01L 24/16; H01L 24/05; H01L 25/0652; H01L 23/552; H01L 2224/16225; H01L 2224/16146; H01L 2224/05025; H01L 2924/19105; H01L 2924/14215

(57) ABSTRACT

The present disclosure is directed to an electronic component package including: a wiring board including a first principal surface and a second principal surface facing each other; an electronic component mounted on the first principal surface; a sealing member provided on the first principal surface for covering the electronic component; and a shield film provided on a surface of the sealing member, wherein the wiring board is provided with a plurality of through holes between the first principal surface and the second principal surface, an electronic component including a columnar terminal is mounted on the first principal surface, and the columnar terminal is inserted into at least one of the through holes from the first principal surface and is exposed on a side of the second principal surface, thereby reducing the size and height of the package.

### CROSS-REFERENCE OF RELATED APPLICATIONS

This application is a continuation of International Patent Application No. PCT/JP2022/007319, filed on Feb. 22, 2022, which claims the benefit of Japanese Patent Application No. 2021-055802, filed on Mar. 29, 2021, the contents all of which are incorporated herein by reference.

### BACKGROUND OF THE DISCLOSURE

### Field of the Disclosure

The present disclosure relates to an electronic component package in which a plurality of electronic components are integrally mounted, and an electronic component unit using the electronic component package. The present disclosure also relates to a method of manufacturing an electronic component package.

### Description of the Related Art

When a space between terminal electrodes is further narrowed along with downsizing of a module, high-density mounting, narrow-gap mounting, and downsizing of the component itself, the possibility of solder short circuit between a bump and an electrode further increases. In a case where a component is mounted on a mother board, we could employ a method including steps of manufacturing in advance a package having a plurality of components mounted on another wiring board, and then mounting the package on the mother board. In this case, a height of the entire package is increased due to the presence of the wiring board. On the other hand, another conformation of a coreless package that does not require the wiring board is also assumed. In the package, there are various types of components, such as a bump component represented by an IC (for example, SW (switch), LNA (low noise amplifier), and PA (power amplifier)), an LGA component represented by various filters and coils, and a side electrode component represented by a capacitor. An electrode conformation exposed from a bottom surface of the coreless package is varied among the bump, the LGA, and the side electrode, and an exposed area of each electrode is greatly different, and there are many challenges in terms of bondability (for example, whether there is no solder open or whether no solder short circuit occurs) at the time of solder bonding with the mother board. Furthermore, there is also another challenge that high positional accuracy of components is required.

FIG. 13 is a cross-sectional view illustrating an example of a conventional electronic component package. The electronic component package includes a plurality of electronic components 11 to 14, a wiring board 91, a sealing resin 81, and a shield film 82. In the wiring board 91, a plurality of vias 92 are provided between the first principal surface thereof and the second principal surface thereof in order to electrically connect a land 93 formed on the first principal surface and a land 94 formed on the second principal surface.

A plurality of solder bumps 11a are provided on a bottom surface of the electronic component 11, and then soldered to the lands 93. A plurality of side electrodes 12a are provided on a side surface and a bottom surface of the electronic component 12, and then soldered to the lands 93. A plurality of planar electrode pads 13a are provided on a bottom surface of the electronic component 13, and then soldered to the lands 93. A plurality of conductor pillars 14a are provided on a bottom surface of the electronic component 14, and then soldered to the lands 93.

Such an electronic component package is mounted on a mother board (not illustrated) having a larger size, and the lands 94 located on the side of the second principal surface are soldered to the lands of the mother board.

Patent Document 1 discloses a relay board including a resin relay board main body, a through conductor portion, a bump forming pad, and a solder bump disposed on a surface of the bump forming pad.
Patent Document 1: JP 2005-243760 A

### BRIEF SUMMARY OF THE DISCLOSURE

In the conventional electronic component package illustrated in FIG. 13, the lands 93 and 94 are provided on both surfaces of the wiring board 91, respectively. Therefore, a distance between the connection terminal of the electronic component and the mother board becomes relatively large. Moreover, a size of the connection terminal itself of the electronic component itself affects a height of the electronic component package. As a result, it is difficult to reduce the size and height of the electronic component package.

Further, in a case where the relay board as in Patent Document 1 is used, a total height of the components is increased because the height of the relay board itself is high. Furthermore, in the stacked configuration of the through conductor, the pad, and the solder bump, the possibility of solder short-circuiting is increased as a gap between the terminals is further narrowed. Incidentally, no method of mounting an electronic component other than the bump component is disclosed.

A possible benefit of the present disclosure is to provide an electronic component package capable of reducing the size and height of the package, and an electronic component unit using the same. Further, another possible benefit of the present disclosure is to provide a method of manufacturing such an electronic component package.

One aspect of the present disclosure provides an electronic component package including: a wiring board including a first principal surface and a second principal surface facing each other; an electronic component mounted on the first principal surface; a sealing member provided on the first principal surface for covering the electronic component; and a shield film provided on a surface of the sealing member, in which the wiring board is provided with a plurality of through holes between the first principal surface and the second principal surface, an electronic component including a solder bump or a conductor pillar as a columnar terminal is mounted on the first principal surface, and the columnar terminal is inserted into at least one of the through holes from the first principal surface and is exposed on a side of the second principal surface.

An electronic component unit according to another aspect of the present disclosure includes: the electronic component package described above; a surface mount electronic component; and a mother board on which the electronic component package and the surface mount electronic component are mounted.

An electronic component unit according to another aspect of the present disclosure includes: the electronic component package described above; a surface mount electronic component; and an antenna board on which the electronic component package and the surface mount electronic component are mounted, the antenna board including a ground conductor and a patch antenna inside.

A method of manufacturing an electronic component package according to still another aspect of the present disclosure, the method includes steps of: preparing a wiring board provided with a plurality of through holes and a plurality of conductor vias between a first principal surface and a second principal surface, and bonding the wiring board on a support plate; placing an electronic component including a solder bump or a conductor pillar as a columnar terminal on the first principal surface, and inserting the columnar terminal from the first principal surface into at least one of the through holes to expose the columnar terminal on a side of the second principal surface; placing an electronic component including a side electrode or a planar electrode pad as a planar terminal on the first principal surface, and directly connecting the planar terminal to at least one of the conductor vias; providing a sealing member on the first principal surface so as to cover the electronic component; providing a shield film on a surface of the sealing member; peeling the support plate from the wiring board; forming a solder resist on the second principal surface; and forming an opening in the solder resist.

A method of manufacturing an electronic component package according to still another aspect of the present disclosure, the method includes steps of: preparing a wiring board including a first principal surface and a second principal surface, and forming a solder resist on the second principal surface; forming an opening in the solder resist; providing a plurality of through holes and a plurality of conductor vias in the wiring board; placing an electronic component including a solder bump or a conductor pillar as a columnar terminal on the first principal surface, and inserting the columnar terminal from the first principal surface into at least one of the through holes to expose the columnar terminal on a side of the second principal surface; placing an electronic component including a side electrode or a planar electrode pad as a planar terminal on the first principal surface, and directly connecting the planar terminal to at least one of the conductor vias; providing a sealing member on the first principal surface so as to cover the electronic component; and providing a shield film on a surface of the sealing member.

According to the present disclosure, it is possible to reduce the size and height of the package.

### BRIEF DESCRIPTION OF THE SEVERAL VIEWS OF THE DRAWINGS

FIG. 1A is a cross-sectional view illustrating an example of an electronic component package according to a first embodiment of the present disclosure, and FIG. 1B is a bottom view thereof; FIG. 1C is a cross-sectional view illustrating a state in which the electronic component package is mounted on a mother board; FIG. 1D is a cross-sectional view illustrating a bonding state of a solder bump; FIG. 1E is a cross-sectional view illustrating a bonding state of a planar electrode pad;

FIG. 2 is a cross-sectional view illustrating an example of an antenna unit on which an electronic component package is mounted;

FIG. 3 is a cross-sectional view illustrating an example of a double-sided mounting board unit on which an electronic component package is mounted;

FIG. 4 is a cross-sectional view illustrating another example of the double-sided mounting board unit on which the electronic component package is mounted;

FIGS. 5A to 5F are cross-sectional views illustrating an example of a method of manufacturing an electronic component package;

FIGS. 6A to 6C are cross-sectional views illustrating another example of the method of manufacturing the electronic component package;

FIG. 7A is a cross-sectional view illustrating an example of an electronic component package according to a fourth embodiment of the present disclosure, and FIG. 7B is a bottom view thereof;

FIG. 8A is a cross-sectional view illustrating an example of an electronic component package according to a fifth embodiment of the present disclosure, and FIG. 8B is a bottom view thereof;

FIG. 9A is a cross-sectional view illustrating a configuration in which a solder resist is formed on the electronic component package illustrated in FIG. 8A, and FIG. 9B is a bottom view thereof;

FIG. 10A is a cross-sectional view illustrating a configuration in which resist openings of the solder resist formed in the electronic component package illustrated in FIG. 9A have the same shape and/or area, and FIG. 10B is a bottom view thereof;

FIG. 11A is a cross-sectional view illustrating a configuration in which a shield connection land located on a left end side and a ground land to which a ground terminal of an electronic component is connected are coupled in the electronic component package illustrated in FIG. 10A, FIG. 11B is a bottom view thereof, and FIG. 11C is a bottom view before the solder resist is formed;

FIG. 12 is a cross-sectional view illustrating a configuration in which a conductor pillar is connected to a conductor land in the electronic component package illustrated in FIGS. 8A to 11A; and

FIG. 13 is a cross-sectional view illustrating an example of a conventional electronic component package.

### DETAILED DESCRIPTION OF THE DISCLOSURE

One aspect of the present disclosure provides an electronic component package including: a wiring board including a first principal surface and a second principal surface facing each other; an electronic component mounted on the first principal surface; a sealing member provided on the first principal surface for covering the electronic component; and a shield film provided on a surface of the sealing member, in which the wiring board is provided with a plurality of through holes between the first principal surface and the second principal surface, an electronic component including a solder bump or a conductor pillar as a columnar terminal is mounted on the first principal surface, and the columnar terminal is inserted into at least one of the through holes from the first principal surface and is exposed on a side of the second principal surface.

According to this configuration, since the columnar terminal is inserted into the through hole from the first principal surface and exposed on the side of the second principal surface, electrical connection, such as solder bonding, with a land of an external mother board can be implemented. Furthermore, since there is no land on both the first principal surface and the second principal surface, a distance between a connection terminal of the electronic component and the mother board can be shortened. Accordingly, it is possible to reduce the size and height of the electronic component package. Moreover, since the columnar terminal is directly exposed on the side of the second principal surface without interposition of any vias, heat generated in the electronic component can be transferred to the mother board at the shortest distance, and thus is less likely to be transferred to the wiring board, and a temperature rise of the wiring board can be suppressed. The columnar terminal may be a large pillar bump for the purpose of heat dissipation in case of a large amount of heat being generated by the electronic component itself. Further, a large amount of heat may be also generated during actual operation. Thus, suppression of the temperature rise of the wiring board is a great advantage.

In the electronic component package according to the present disclosure, the wiring board may be provided with a plurality of conductor vias between the first principal surface and the second principal surface, an electronic component including a side electrode or a planar electrode pad as a planar terminal may be mounted on the first principal surface, and the planar terminal may be directly connected to at least one of the conductor vias.

According to this configuration, since the planar terminal is directly connected to the conductor via, electrical connection, such as solder bonding, with the land of the external mother board can be implemented without interposing any lands. Accordingly, it is possible to reduce the size and height of the electronic component package.

In the electronic component package according to the present disclosure, a conductor land that connects to an external board is provided on the second principal surface, and the columnar terminal or at least one of the conductor vias may be directly connected to the conductor land. According to this configuration, by providing the conductor land that connects to the external board on the second principal surface, the height thereof is increased, but by increasing the positional accuracy of the conductor land, the positional accuracy of mounting on the external mother board can be enhanced without depending on the mounting accuracy of the electronic components on the wiring board.

In the electronic component package according to the present disclosure, a solder resist may be formed on the second principal surface such that the columnar terminal and at least one of the conductor vias are exposed on the side of the second principal surface, or such that the conductor land to which the columnar terminal and at least one of the conductor vias are connected is exposed on the side of the second principal surface.

According to this configuration, since an area that can be solder-bonded to the land of the external mother board is limited by the solder resist, the size and height of solder fillet can be controlled.

In the electronic component package according to the present disclosure, regions exposed on the side of the second principal surface may have the same shape and/or area.

According to this configuration, the size and height of the solder fillet to be solder-bonded to the land of the external mother board can be equalized. This makes it possible to stabilize the characteristics of solder bonding.

In the electronic component package according to the present disclosure, a shield connection land connected to the shield film may be provided on the second principal surface.

According to this configuration, electrical connection between the shield film and a ground of the external mother board can be implemented by connection between the shield connection land and the ground land of the external mother board.

In the electronic component package according to the present disclosure, the shield connection land may be coupled to a ground land to which a ground terminal of the electronic component is connected.

According to this configuration, solder bonding between the shield connection land and the ground land of the external mother board can be omitted.

An electronic component unit according to another aspect of the present disclosure includes: the electronic component package described above; a surface mount electronic component; and a mother board on which the electronic component package and the surface mount electronic component are mounted.

According to this configuration, it is possible to reduce the size and height of the electronic component unit.

In the electronic component unit according to the present disclosure, the mother board includes a first principal surface and a second principal surface facing each other, and the electronic component package and/or the surface mount electronic component may be mounted on both the first principal surface and the second principal surface.

According to this configuration, it is possible to reduce the size and height of the electronic component unit. Further, the double-sided mounting can increase a mounting density of the electronic component.

An electronic component unit according to another aspect of the present disclosure includes: the electronic component package described above; a surface mount electronic component; and an antenna board on which the electronic component package and the surface mount electronic component are mounted, the antenna board including a ground conductor and a patch antenna inside. According to this configuration, it is possible to reduce the size and height of the electronic component unit.

A method of manufacturing an electronic component package according to still another aspect of the present disclosure, the method includes steps of: preparing a wiring board provided with a plurality of through holes and a plurality of conductor vias between a first principal surface and a second principal surface, and bonding the wiring board on a support plate; placing an electronic component including a solder bump or a conductor pillar as a columnar terminal on the first principal surface, and inserting the columnar terminal from the first principal surface into at least one of the through holes to expose the columnar terminal on a side of the second principal surface; placing an electronic component including a side electrode or a planar electrode pad as a planar terminal on the first principal surface, and directly connecting the planar terminal to at least one of the conductor vias; providing a sealing member on the first principal surface so as to cover the electronic component; providing a shield film on a surface of the sealing member; peeling the support plate from the wiring board; forming a solder resist on the second principal surface; and forming an opening in the solder resist.

According to this configuration, it is possible to reduce the size and height of the electronic component package.

A method of manufacturing an electronic component package according to still another aspect of the present disclosure, the method includes the steps of: preparing a wiring board including a first principal surface and a second principal surface, and forming a solder resist on the second principal surface; forming an opening in the solder resist; providing a plurality of through holes and a plurality of conductor vias in the wiring board; placing an electronic component including a solder bump or a conductor pillar as a columnar terminal on the first principal surface, and inserting the columnar terminal from the first principal surface into at least one of the through holes to expose the columnar terminal on a side of the second principal surface; placing an electronic component including a side electrode or a planar electrode pad as a planar terminal on the first principal surface, and directly connecting the planar terminal to at least one of the conductor vias; providing a sealing member on the first principal surface so as to cover the electronic component; and providing a shield film on a surface of the sealing member.

According to this configuration, it is possible to reduce the size and height of the electronic component package.

### First Embodiment

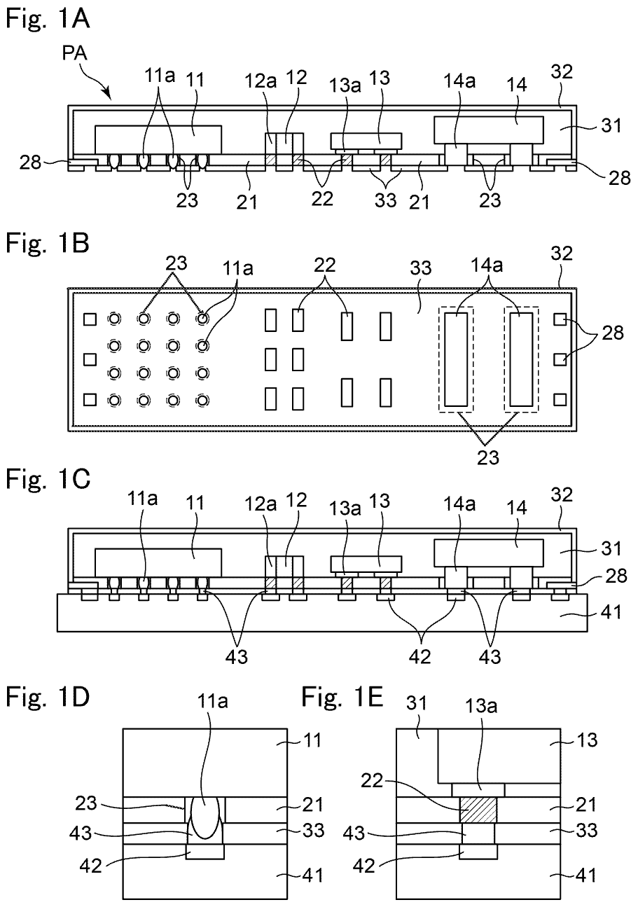

FIG. 1A is a cross-sectional view illustrating an example of an electronic component package PA according to a first embodiment of the present disclosure, and FIG. 1B is a bottom view thereof. FIG. 1C is a cross-sectional view illustrating a state in which the electronic component package PA is mounted on a mother board. FIG. 1D is a cross-sectional view illustrating a bonding state of a solder bump 11a. FIG. 1E is a cross-sectional view illustrating a bonding state of a planar electrode pad 13a.

As illustrated in FIG. 1A, the electronic component package PA includes a plurality of electronic components 11 to 14, a wiring board 21, a sealing resin 31, and a shield film 32. Here, four electronic components 11 to 14 are exemplified, but five or more electronic components may be mounted. The electronic component 11 is, for example, a bump component such as SW, LNA, or PA, and a plurality of solder bumps 11a are provided on a bottom surface thereof. The electronic component 12 is, for example, a chip-shaped side electrode component such as a capacitor, an inductor, or a resistor, and a plurality of side electrodes 12a are provided on a side surface and a bottom surface thereof. The electronic component 13 is, for example, an LGA component such as various filters and coils, and a plurality of planar electrode pads 13a are provided on a bottom surface thereof. The electronic component 14 is, for example, a pillar component such as a semiconductor chip, and a plurality of conductor pillars 14a are provided on a bottom surface thereof. When the pillars 14a are made of copper (Cu), each of the conductor pillars 14a is referred to as a copper pillar, and is also referred to as a copper post or a copper column in another name.

The wiring board 21 is made of an electrically insulating material and includes a first principal surface and a second principal surface facing each other, and the electronic components 11 to 14 are mounted on the first principal surface. The sealing resin 31 is provided on the first principal surface so as to cover the electronic components 11 to 14. The shield film 32 made of a conductive material is provided on a surface of the sealing member 31.

The wiring board 21 is provided with a plurality of conductor vias 22 and a plurality of through holes 23 between the first principal surface and the second principal surface. Each of the through holes 23 is formed to be slightly larger than outer dimensions of the solder bump 11a of the electronic component 11 and the conductor pillar 14a of the electronic component 14. Each of the conductor vias 22 can be formed by forming a through hole between the first principal surface and the second principal surface, and then either plating the inside of the through hole or filling the through hole with a conductive material.

When the electronic components 11 to 14 are mounted on the first principal surface of the wiring board 21, the solder bump 11a and the conductor pillar 14a are inserted into each of the through holes 23 and exposed on a side of the second principal surface. Furthermore, the side electrode 12a and the planar electrode pad 13a are directly connected to each of the conductor vias 22, thereby ensuring electrical connection therebetween.

On the second principal surface of the wiring board 21, a shield connection land 28 connected to the shield film 32 is provided. Here, a case where the shield connection lands 28 are provided at left and right end portions of the second principal surface is exemplified, but the shield connection lands may be provided at portions other than the left and right end portions.

As illustrated in FIG. 1B, a solder resist 33 is formed on the second principal surface of the wiring board 21 such that the solder bump 11a and the conductor pillar 14a, which are columnar terminals, the conductor via 22, and the shield connection land 28 are exposed on the side of the second principal surface. Here, the solder bump 11a and the conductor pillar 14a are formed by an over-resist method.

Next, as illustrated in FIG. 1C, a mother board 41 has a plurality of lands 42 for electrical connection with the electronic components. The shield connection lands 28 are also connected to the lands 42.

As illustrated in FIGS. 1D and 1E, a solder paste 43 is applied in advance onto the lands 42 to be soldered, and when the electronic component package PA is mounted on the mother board 41 and subjected to reflow heating, the solder paste 43 is melted. At this time, the solder bump 11a and the land 42 are electrically connected with each other. Similarly, the conductor pillar 14a and the land 42 are electrically connected with each other. Furthermore, electrical connection between the conductor via 22 to which the side electrode 12a and the planar electrode pad 13a are connected and the land 42 is also implemented. The solder resist 33 prevents the molten solder paste 43 from leaking to the surroundings.

Thus, the electronic component unit in which the electronic component package PA is mounted on the first principal surface of the wiring board 21 is obtained. Since the first principal surface and the second principal surface of the wiring board 21 do not have lands as in the above-mentioned related art, it is possible to reduce the size and height of the electronic component package PA and the electronic component unit. Furthermore, heat transfer from the columnar terminal to the wiring board can also be suppressed.

### Second Embodiment

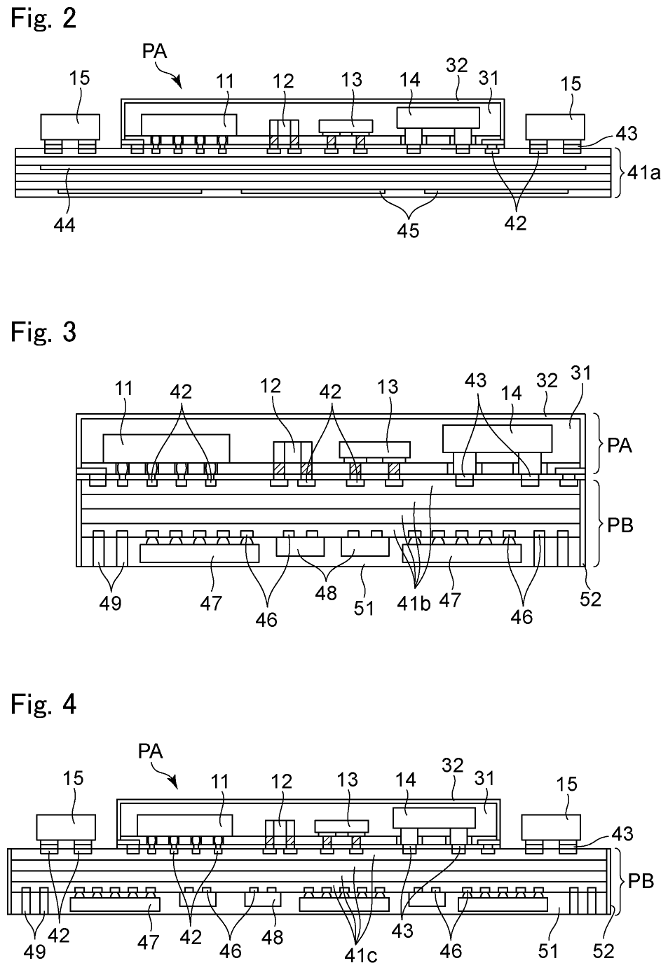

FIG. 2 is a cross-sectional view illustrating an example of an antenna unit on which an electronic component package PA is mounted. The antenna unit includes the electronic component package PA described above, a surface mount electronic component 15 separate from the electronic component package PA, and an antenna board 41a. A principal surface of the antenna board 41a is provided with a plurality of lands 42 for electrical connection with electronic components, and includes a ground plane 44 and a patch antenna 45 therein. Thus, a height of the electronic component package PA can be reduced, so that a height of the antenna unit can be reduced.

FIG. 3 is a cross-sectional view illustrating an example of a double-sided mounting board unit on which the electronic component package PA is mounted. The double-sided mounting board unit includes the electronic component package PA described above and a second electronic component package PB. The second electronic component package PB includes a wiring board 41b, electronic components 47 and 48, an input/output via 49, and the like. A plurality of lands 42 for electrical connection with the electronic component package PA is provided on an upper surface of the wiring board 41b. A plurality of lands 46 for electrical connection with the electronic components 47 and 48 and the input/output via 49 are provided on a lower surface of the wiring board 41b. Similarly to the electronic component package PA, the second electronic component package PB is covered with a sealing resin 51, and a shield film 52 made of a conductive material is provided on a surface thereof. Thus, the height of the electronic component package PA can be reduced, so that the height of the double-sided mounting board unit can be reduced. By separating the shields of the electronic component package PA and the second electronic component package PB, the shield function of each electronic component can be enhanced, and interference between the electronic component package PA and the second electronic component package PB through the shield can be suppressed.

FIG. 4 is a cross-sectional view illustrating another example of the double-sided mounting board unit on which the electronic component package PA is mounted. The double-sided mounting board unit includes the electronic component packages PA and PB described above and a surface mount electronic component 15 separate from the electronic component packages PA and PB. Thus, the height of the electronic component package PA can be reduced, so that the height of the double-sided mounting board unit can be reduced. When viewed as the entire package, a partial resin mold structure of the portion excluding the surface mount electronic component 15 can be easily obtained. Note that the surface mount electronic component 15 may be, for example, a connector.

### Third Embodiment

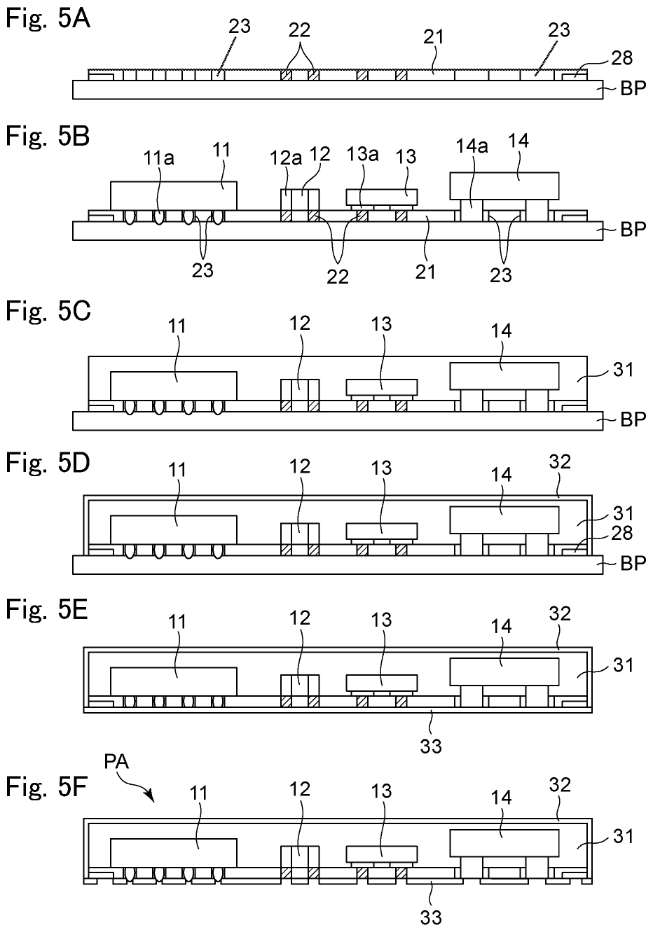

FIGS. 5A to 5F are cross-sectional views illustrating an example of a method of manufacturing the electronic component package PA. First, as illustrated in FIG. 5A, a wiring board 21 in which a plurality of through holes 23 and a plurality of conductor vias 22 are provided between a first principal surface and a second principal surface is prepared and attached onto a support plate BP. The support plate BP is used to maintain a shape of the thin wiring board 21, and is finally removed. Note that a shield connection land 28 is provided on the second principal surface of the wiring board 21 so that a side surface is exposed.

Next, as illustrated in FIG. 5B, electronic components 11 and 14 including a solder bump 11a or a conductor pillar 14a as a columnar terminal are placed on the first principal surface, and the solder bump 11a or the conductor pillar 14a is inserted into the through hole 23 from the first principal surface to be exposed on a side of the second principal surface. Before or after this, electronic components 12 and 13 including a side electrode 12a or a planar electrode pad 13a as a planar terminal are placed on the first principal surface, and the side electrode 12a or the planar electrode pad 13a is directly connected to the conductor via 22.

Next, as illustrated in FIG. 5C, a sealing resin 31 is provided on the first principal surface of the wiring board 21 so as to cover the electronic components 11 to 14.

Next, as illustrated in FIG. 5D, a shield film 32 is provided on a surface of the sealing resin 31 by using e.g., vacuum deposition, sputtering, plating, or the like. At this time, the shield film 32 is electrically connected to the shield connection lands 28 whose side surfaces are exposed.

Next, as illustrated in FIG. 5E, the support plate BP is peeled off from the wiring board 21. Subsequently, a solder resist 33 is formed on the entire second principal surface of the wiring board 21.

Next, as illustrated in FIG. 5F, openings are formed in the solder resist 33 to expose the solder bump 11a, the conductor pillar 14a, the conductor via 22, and the shield connection land 28 on the side of the second principal surface.

Thus, the electronic component package PA is obtained. Since the first principal surface and the second principal surface of the wiring board 21 do not have lands as in the above-mentioned related art, it is possible to reduce the height of the electronic component package PA. Furthermore, heat transfer from the columnar terminal to the wiring board can also be suppressed.

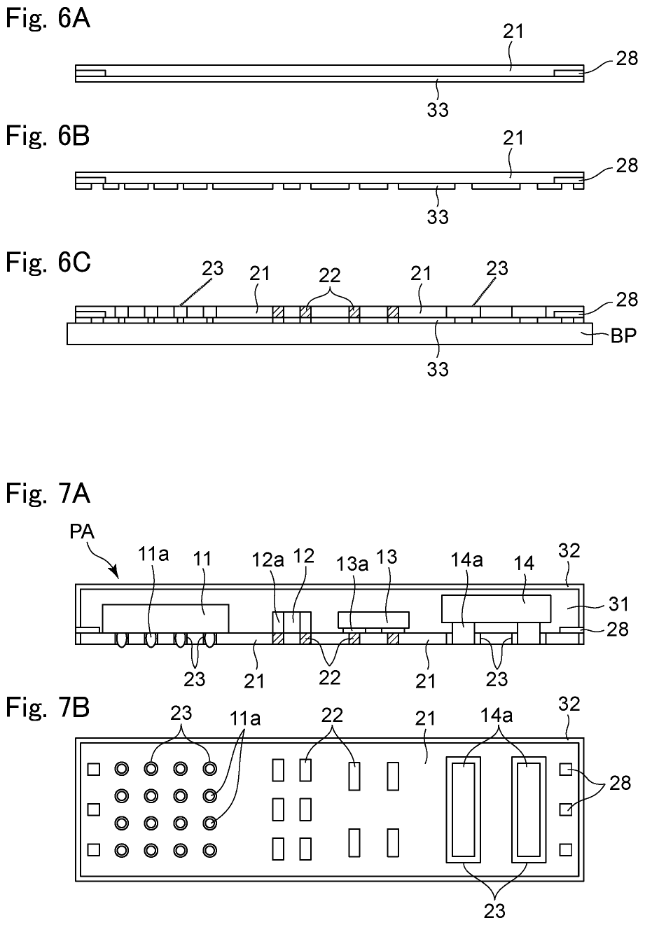

FIGS. 6A to 6C are cross-sectional views illustrating another example of the method of manufacturing the electronic component package PA. First, as illustrated in FIG. 6A, a wiring board 21 including a first principal surface and a second principal surface is prepared. On the second principal surface of the wiring board 21, a shield connection land 28 is provided so that a side surface is exposed. Subsequently, a solder resist 33 is formed on the second principal surface.

Next, as illustrated in FIG. 6B, openings are formed in the solder resist 33. The openings are disposed so as to expose a solder bump 11a and a conductor pillar 14a of electronic components 11 to 14 to be mounted in a subsequent process, a conductor via 22, and the shield connection land 28 on a side of the second principal surface.

Next, as illustrated in FIG. 6C, first, a through hole for the conductor via 22 is formed in the wiring board 21. Subsequently, in a case where the wiring board 21 is made of ceramic, the through hole is filled with a conductive paste. In a case where the wiring board 21 is made of a resin board, the through hole is plated or filled with a conductive paste. As a result, the conductor via 22 is formed. As a material of the resin board, for example, a thermoplastic resin such as liquid crystal polymer (LCP) can be used. However, a thermoplastic resin other than the liquid crystal polymer may be used. For example, polyether ether ketone (PEEK), polyether imide (PEI), or polyimide (PI) may be used. Furthermore, a thermosetting resin such as epoxy or unsaturated polyester may be used. Next, the through hole 23 for the solder bump 11a or the conductor pillar 14a is formed. Subsequently, the wiring board 21 is attached onto a support plate BP. The support plate BP is used to maintain a shape of the thin wiring board 21, and is finally removed.

Hereinafter, since the steps are similar to those in FIGS. 5B to 5F, the steps will be described with reference to FIGS. 5B to 5F.

Next, as illustrated in FIG. 5B, electronic components 11 and 14 including a solder bump 11a or a conductor pillar 14a as a columnar terminal are placed on the first principal surface, and the solder bump 11a or the conductor pillar 14a is inserted into the through hole 23 from the first principal surface to be exposed on a side of the second principal surface. Before or after this, electronic components 12 and 13 including a side electrode 12a or a planar electrode pad 13a as a planar terminal are placed on the first principal surface, and the side electrode 12a or the planar electrode pad 13a is directly connected to the conductor via 22.

Next, as illustrated in FIG. 5C, a sealing resin 31 is provided on the first principal surface of the wiring board 21 so as to cover the electronic components 11 to 14.

Next, as illustrated in FIG. 5D, a shield film 32 is provided on a surface of the sealing resin 31 by using e.g., vacuum deposition, sputtering, plating, or the like. At this time, the shield film 32 is electrically connected to the shield connection lands 28 whose side surfaces are exposed.

Next, as illustrated in FIG. 5E, the support plate BP is peeled off from the wiring board 21. Thus, the electronic component package PA similar to that in FIG. 5F is obtained. Since the first principal surface and the second principal surface of the wiring board 21 do not have lands as in the above-mentioned related art, it is possible to reduce the height of the electronic component package PA. Furthermore, heat transfer from the columnar terminal to the wiring board can also be suppressed.

### Fourth Embodiment

FIG. 7A is a cross-sectional view illustrating an example of an electronic component package PA according to a fourth embodiment of the present disclosure, and FIG. 7B is a bottom view thereof. The electronic component package PA is similar to that illustrated in FIG. 1A, but the formation of the solder resist 33 is omitted.

Since a first principal surface and a second principal surface of a wiring board 21 do not have lands as in the above-mentioned related art, it is possible to reduce the size and height of the electronic component package PA. Furthermore, heat transfer from the columnar terminal to the wiring board can also be suppressed.

### Fifth Embodiment

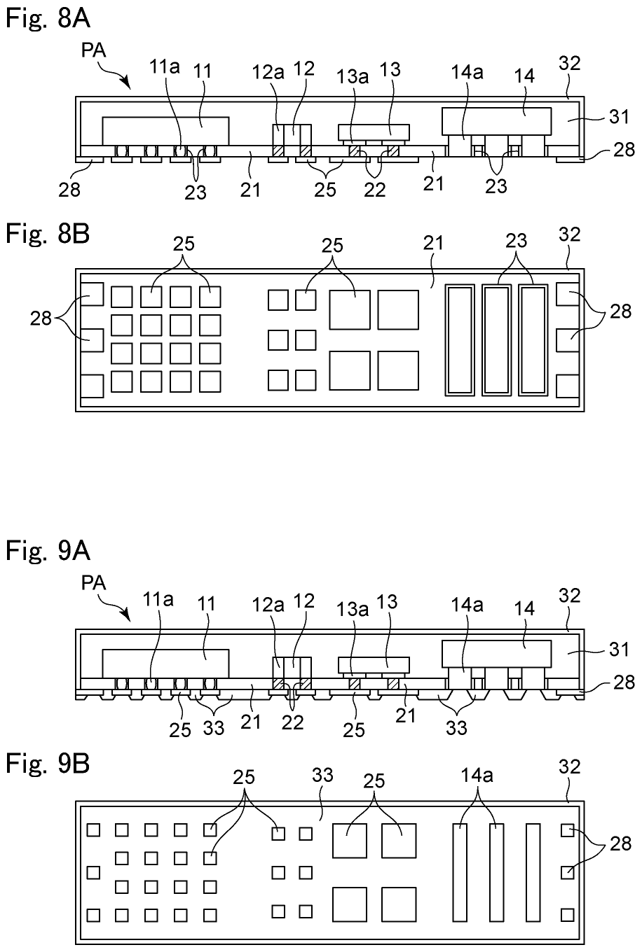

FIG. 8A is a cross-sectional view illustrating an example of an electronic component package PA according to a fifth embodiment of the present disclosure, and FIG. 8B is a bottom view thereof. This electronic component package PA is similar to that illustrated in FIG. 1A, but a conductor land 25 for connection with an external board, for example, a mother board is provided on a second principal surface of a wiring board 21, and formation of a solder resist 33 is omitted. Details of the electronic component package PA have been described with reference to FIGS. 1A to 1E.

A solder bump 11a as a columnar terminal, and a side electrode 12a and a planar electrode pad 13a as planar terminals are directly connected to the conductor land 25. Note that a conductor pillar 14a is directly connected to a land of an external board without passing through the conductor land 25. In general, the conductor pillar 14a is larger than the solder bump 11a, and is made of a metal formed by plating or the like, unlike solder. For this reason, it is not necessary to be further connected to the metal conductor land 25, in other words, the conductor pillar has an advantage that it can be used as it is as a conductor land.

When providing such a conductor land 25, the height thereof is increased, but by increasing the positional accuracy of the conductor land 25, the positional accuracy of mounting on the external mother board can be enhanced without depending on the mounting accuracy of the electronic components on the wiring board. Furthermore, heat transfer from the columnar terminal to the wiring board can also be suppressed.

FIG. 9A is a cross-sectional view illustrating a configuration in which a solder resist 33 is formed in the electronic component package PA illustrated in FIG. 8A, and FIG. 9B is a bottom view thereof. Here, the conductor land and the conductor pillar 14a are formed by an over-resist method.

By forming such a solder resist 33, since an area that can be solder-bonded to the land of the external mother board is limited by the solder resist, the size and height of solder fillet can be controlled.

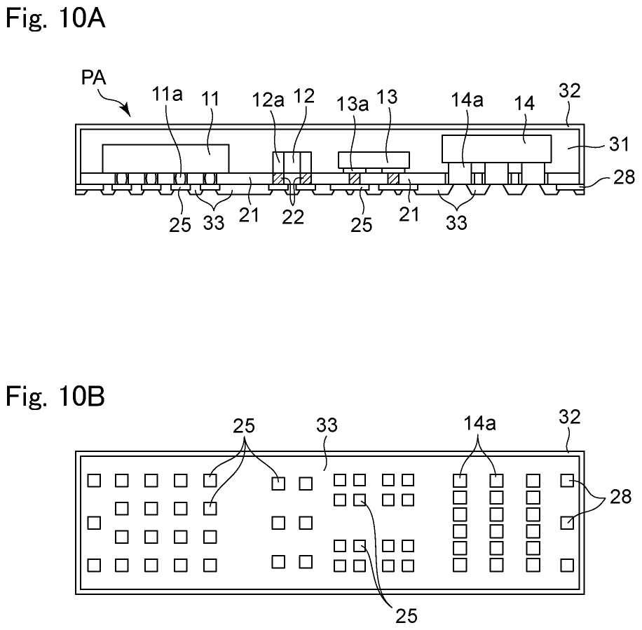

FIG. 10A is a cross-sectional view illustrating a configuration in which resist openings of the solder resist 33 formed in the electronic component package PA illustrated in FIG. 9A, that is, regions where the conductor land 25 and the conductor pillar 14a are exposed on a side of the second principal surface have the same shape and/or area, and FIG. 10B is a bottom view thereof.

By forming the resist openings as uniform as possible, the size and height of the solder fillet to be solder-bonded to the land of the external mother board can be equalized. This makes it possible to stabilize the characteristics of solder bonding.

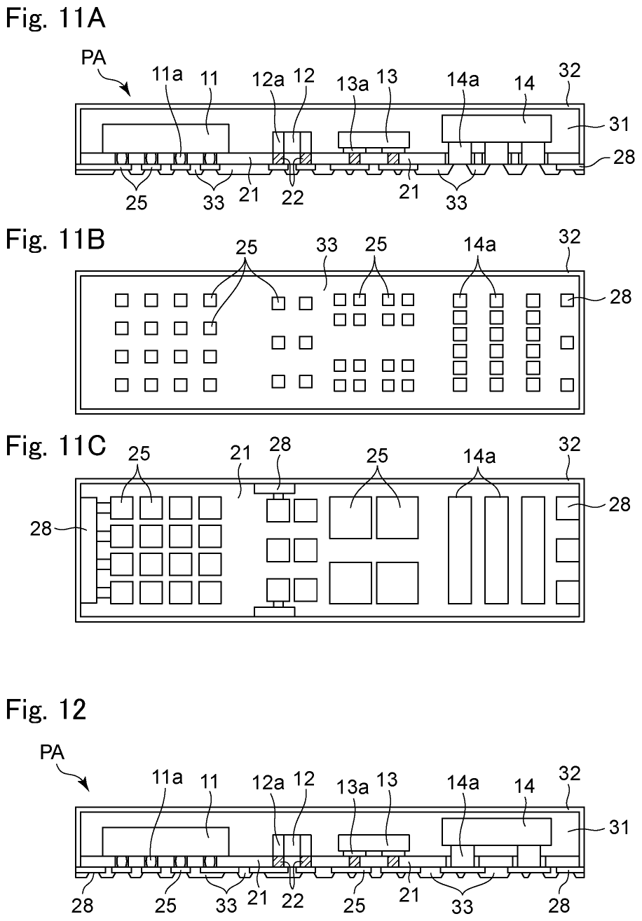

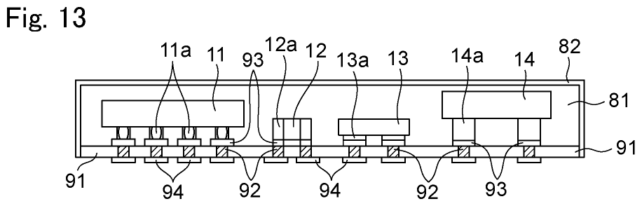

FIG. 11A is a cross-sectional view illustrating a configuration in which a shield connection land 28 located on the left end side and a ground land to which a ground terminal of the electronic component 11 is connected are coupled in the electronic component package PA illustrated in FIG. 10A, FIG. 11B is a bottom view thereof, and FIG. 11C is a bottom view before the solder resist 33 is formed.

By coupling the conductors having the ground potential in this manner, solder bonding between the shield connection land and the ground land of the external mother board can be omitted. Therefore, the resist opening can also be omitted for the left shield connection land 28. On the other hand, since the right shield connection land 28 is not connected to the ground land, the resist opening is formed.

FIG. 12 is a cross-sectional view illustrating a configuration in which the conductor pillar 14a is connected to the conductor land 25 in the electronic component package PA illustrated in FIGS. 8A to 11A. A connection area with the mother board can be increased by widening a heat transfer path using the conductor land 25 for the conductor pillar 14a particularly requiring heat dissipation.

Although the present disclosure has been fully described in connection with preferred embodiments with reference to the accompanying drawings, various changes and modifications will be apparent to those skilled in the art. Such changes and modifications are to be understood as included within the scope of the present disclosure as defined by the appended claims unless they depart therefrom.

The present disclosure is industrially very useful in that the electronic component package can be reduced in size and height.
10 to 14 electronic component
11a solder bump
12a side electrode
13a planar electrode pad
14a conductor pillar
21 wiring board
22 conductor via
23 through holes
conductor land
28 shield connection land
31 sealing resin
32 shield film
33 solder resist
41 mother board
42 land
PA electronic component package

1. An electronic component package comprising:
a wiring board including a first principal surface and a second principal surface facing each other;
an electronic component mounted on the first principal surface;
a sealing member provided on the first principal surface for covering the electronic component; and
a shield film provided on a surface of the sealing member,
wherein the wiring board is provided with a plurality of through holes between the first principal surface and the second principal surface,
an electronic component including a columnar terminal is mounted on the first principal surface, and
the columnar terminal is inserted into at least one of the through holes from the first principal surface and is exposed on a side of the second principal surface.

2. The electronic component package according to claim 1, wherein the wiring board is provided with a plurality of conductor vias between the first principal surface and the second principal surface,
an electronic component including a planar terminal is mounted on the first principal surface, and
the planar terminal is directly connected to at least one of the conductor vias.

3. The electronic component package according to claim 2, wherein a conductor land connecting to an external board is provided on the second principal surface, and
the columnar terminal or at least one of the conductor vias is directly connected to the conductor land.

4. The electronic component package according to claim 3, wherein a solder resist is provided on the second principal surface such that the columnar terminal and at least one of the conductor vias are exposed on the side of the second principal surface, or such that the conductor land to which the columnar terminal and at least one of the conductor vias are connected is exposed on the side of the second principal surface.

5. The electronic component package according to claim 4, wherein regions exposed on the side of the second principal surface have a same shape and/or area.

6. The electronic component package according to claim 1, wherein a shield connection land connected to the shield film is provided on the second principal surface.

7. The electronic component package according to claim 6, wherein the shield connection land is coupled to a ground land to which a ground terminal of the electronic component is connected.

8. An electronic component unit comprising:
the electronic component package according to claim 1;
a surface mount electronic component; and
a mother board on which the electronic component package and the surface mount electronic component are mounted.

9. The electronic component unit according to claim 8, wherein
the mother board includes a first principal surface and a second principal surface facing each other, and
the electronic component package and/or the surface mount electronic component is mounted on both the first principal surface and the second principal surface.

10. An electronic component unit comprising:
the electronic component package according to claim 1;
a surface mount electronic component; and
an antenna board on which the electronic component package and the surface mount electronic component are mounted, the antenna board including a ground conductor and a patch antenna inside.

11. A method of manufacturing an electronic component package, the method comprising the steps of:
preparing a wiring board provided with a plurality of through holes and a plurality of conductor vias between a first principal surface and a second principal surface, and bonding the wiring board on a support plate;
placing an electronic component including a columnar terminal on the first principal surface, and inserting the columnar terminal from the first principal surface into at least one of the through holes to expose the columnar terminal on a side of the second principal surface;
placing an electronic component including a planar terminal on the first principal surface, and directly connecting the planar terminal to at least one of the conductor vias;
providing a sealing member on the first principal surface so as to cover the electronic component;
providing a shield film on a surface of the sealing member;
peeling the support plate from the wiring board;
forming a solder resist on the second principal surface; and
forming an opening in the solder resist.

12. A method of manufacturing an electronic component package, the method comprising the steps of:
preparing a wiring board including a first principal surface and a second principal surface, and forming a solder resist on the second principal surface;
forming an opening in the solder resist;
providing a plurality of through holes and a plurality of conductor vias in the wiring board;
placing an electronic component including a columnar terminal on the first principal surface, and inserting the columnar terminal from the first principal surface into at least one of the through holes to expose the columnar terminal on a side of the second principal surface;
placing an electronic component including a planar terminal on the first principal surface, and directly connecting the planar terminal to at least one of the conductor vias;
providing a sealing member on the first principal surface so as to cover the electronic component; and
providing a shield film on a surface of the sealing member.

13. An electronic component unit comprising:
the electronic component package according to claim 2;
a surface mount electronic component; and
a mother board on which the electronic component package and the surface mount electronic component are mounted.

14. An electronic component unit comprising:
the electronic component package according to claim 3;
a surface mount electronic component; and
a mother board on which the electronic component package and the surface mount electronic component are mounted.

15. An electronic component unit comprising:
the electronic component package according to claim 4;
a surface mount electronic component; and
a mother board on which the electronic component package and the surface mount electronic component are mounted.

16. An electronic component unit comprising:
the electronic component package according to claim 5;
a surface mount electronic component; and
a mother board on which the electronic component package and the surface mount electronic component are mounted.

17. An electronic component unit comprising:
the electronic component package according to claim 6;
a surface mount electronic component; and
a mother board on which the electronic component package and the surface mount electronic component are mounted.

18. An electronic component unit comprising:
the electronic component package according to claim 7;
a surface mount electronic component; and
a mother board on which the electronic component package and the surface mount electronic component are mounted.

19. An electronic component unit comprising:
the electronic component package according to claim 2;
a surface mount electronic component; and
an antenna board on which the electronic component package and the surface mount electronic component are mounted, the antenna board including a ground conductor and a patch antenna inside.

20. An electronic component unit comprising:
the electronic component package according to claim 3;
a surface mount electronic component; and
an antenna board on which the electronic component package and the surface mount electronic component are mounted, the antenna board including a ground conductor and a patch antenna inside.
